(19) United States
(12) Patent Application Publication
(10) Pub. No.: US 2026/0343798 A1
(43) Pub. Date: Oct. 29, 2026

(54) APPARATUS, SYSTEM, AND METHODS FOR MODULAR LIQUID-COOLED COMPONENT RACK WITH HOT-SWAP CAPABILITY

(71) Applicant: Iceotope Group Limited, South Yorkshire (GB)

(72) Inventors: Neil Edmunds, Ylöjärvi (FI); Nathan Longhurst, Chesterfield (GB); David Amos, Sheffield (GB)

(73) Assignee: Iceotope Group Limited, South Yorkshire (GB)

(21) Appl. No.: 19/656,658

(22) Filed: Apr. 23, 2026

Related U.S. Application Data
(60) Provisional application No. 63/793,411, filed on Apr. 23, 2025.

(51) Int. Cl. H05K 7/20

(52) U.S. Cl. CPC H05K 7/20254; H05K 7/20272; H05K 7/20436

(57) ABSTRACT

A system for cooling electronic components includes a component rack and one or more component modules disposed within the component rack. Each of the one or more component modules includes one or more internal components, a dielectric coolant contained within an internal volume of each of the one or more component modules, and a pump configured to circulate the dielectric coolant within the component module. The dielectric coolant partially submerges the one or more internal components. The system further includes one or more cold plates including an internal cavity configured to receive an external coolant. Heat absorbed by the dielectric coolant from the one or more internal components is transferred to the external coolant via the one or more cold plates.

### CROSS-REFERENCE TO RELATED APPLICATIONS

This application claims the benefit of U.S. Provisional Application No. 63/793,411, titled APPARATUS, SYSTEM, AND METHODS FOR MODULAR LIQUID-COOLED COMPONENT RACK WITH HOT-SWAP CAPABILITY, filed Apr. 23, 2025, which is hereby incorporated by reference in its entirety.

### FIELD OF THE PRESENT DISCLOSURE

The present disclosure is directed to apparatus, system, and methods for modular liquid-cooled component rack with hot-swap capability. Particularly, the present disclosure is directed to apparatus, system, and methods for modular liquid-cooled component racks incorporating one or more cold plates for cooling one or more cooling modules therein.

### INTRODUCTION

Modern electronic systems face increasingly stringent requirements for thermal management as they integrate more powerful components into confined spaces. In various computing, telecommunications, and industrial applications, there is a continuous drive to improve cooling efficiency and ensure reliable operation under high-density conditions. As electronic devices, such as power supplies become more compact, the need for effective cooling solutions that efficiently dissipate heat while maintaining system integrity becomes increasingly significant. Existing methods have evolved from traditional air cooling to more advanced cooling systems that utilize liquid-based approaches. This evolution underscores the importance of managing heat in environments where continuous and uninterrupted performance is essential.

In many applications, it is desirable to achieve highly efficient cooling while also ensuring that electronic components remain serviceable and maintainable without interrupting overall system operation. Efforts have been made to develop systems that not only remove heat effectively but also facilitate continuous operation during routine servicing, reducing downtime, and enhancing overall system resilience. As such, there is a demand for systems that support hot-swap functionality that balance high thermal efficiency with the ease of component replacement.

A general challenge exists in reconciling high-performance cooling methods with the operational flexibility required in modern electronic assemblies. Many existing solutions necessitate temporary cessation of cooling operations to service or replace functional units, potentially introducing thermal stress and compromising reliability. Moreover, the integration of cooling circuits with electronic modules often involves complex connectivity and dependency issues, which can limit overall system uptime. Addressing these challenges requires a careful balance of cooling efficiency and ease of maintenance to achieve uninterrupted thermal management in systems that require individual components to be serviced or replaced quickly.

As such, there exists a desire for a system that enables a user to hot swap liquid cooled components while not interfering with the cooling of other component modules in the system.

Such a system incorporating such advantageous features may be described herein.

### SUMMARY

This Summary is provided to introduce a selection of concepts in a simplified form that are further described below in the Detailed Description. This Summary is not intended to identify key features or essential features, nor is it intended to limit the scope of the claims included herewith.

According to an aspect of the present disclosure, a system for cooling electronic components may be provided. The system may comprise a component rack and one or more component modules disposed within the component rack. Each of the one or more component modules may include one or more internal components and a dielectric coolant contained within an internal volume of each of the one or more component modules. The dielectric coolant may at least partially submerge the one or more internal components. Each of the one or more component modules may include a pump configured to circulate the dielectric coolant within the component module. The system may comprise one or more cold plates including an internal cavity configured to receive an external coolant. Heat absorbed by the dielectric coolant from the one or more internal components may be transferred to the external coolant via the one or more cold plates.

According to other aspects of the present disclosure, the system may include one or more of the following features. The internal cavity may include a plurality of heat fins to increase surface area within the internal cavity. The one or more cold plates may further comprise a coolant input and a coolant output. Each of the coolant input and the coolant output may be disposed at an end of the one or more cold plates. The internal cavity may receive cool external coolant via the coolant input. The internal cavity may reject warmed external coolant via the coolant output. The component rack may include one or more component module sockets that receive and house the one or more component modules. The one or more cold plates may serve as a base for the one or more component module sockets within the component rack. Each of the one or more component module sockets may include a notch configured to receive the one or more cold plates. The one or more component modules may further comprise a cooling hose that transfers the dielectric coolant from a first end of the component module to a second end of the component module via the pump. A bottom surface of each of the one or more component modules may be in thermal contact with a top surface of at least one of the one or more cold plates. A thermal interface material may be disposed between the bottom surface of each of the one or more component modules and the top surface of the one or more cold plates. The component rack may include a spring system configured to press each of the one or more component modules toward the one or more cold plates. The spring system may include one or more springs positioned in a roof of each of the one or more component module sockets. The one or more component modules may further comprise a heat exchange assembly in thermal contact with the one or more cold plates. The heat exchange assembly may include a plurality of heat fins configured to increase surface area within the component module.

According to another aspect of the present disclosure, a system for cooling electronic components may be provided. The system may comprise a component rack including one or more component module sockets and one or more component modules disposed within each of the one or more component module sockets. Each of the one or more component modules may include one or more internal components. Each of the one or more component modules may include a dielectric coolant contained within an internal volume of each of the one or more component modules. The dielectric coolant may partially submerge the one or more internal components. Each of the one or more component modules may include a pump configured to circulate the dielectric coolant within the component module. The system may comprise one or more cold plates including an internal cavity configured to receive an external coolant. Heat absorbed by the dielectric coolant from the one or more internal components may be transferred to the external coolant via the one or more cold plates.

According to other aspects of the present disclosure, the system may include one or more of the following features. The internal cavity may include a plurality of heat fins to increase surface area within the internal cavity. The one or more cold plates may further comprise a coolant input and a coolant output. Each of the coolant input and the coolant output may be disposed at an end of the one or more cold plates. The internal cavity may receive cool external coolant via the coolant input. The internal cavity may reject warmed external coolant via the coolant output. The one or more component modules may further comprise a heat exchange assembly in thermal contact with the one or more cold plates. The heat exchange assembly may include a plurality of heat fins configured to increase surface area within the component module. The one or more cold plates may serve as a base for the one or more component module sockets within the component rack. Each of the one or more component module sockets may include a notch configured to receive the one or more cold plates.

### BRIEF DESCRIPTION OF FIGURES

FIG. 1 illustrates an embodiment of a modular component rack in a horizontal configuration, according to aspects of the present disclosure.

FIG. 2 illustrates an embodiment of the modular component rack of FIG. 1 in a vertical configuration, according to aspects of the present disclosure.

FIG. 3 illustrates an embodiment of a rear portion of a casing for the modular component rack, according to aspects of the present disclosure.

FIG. 4 illustrates an embodiment of the modular component rack with a component module being inserted, according to aspects of the present disclosure.

FIG. 5A illustrates an embodiment of a component module partially inserted into a casing, according to aspects of the present disclosure.

FIG. 5B illustrates an embodiment of the component module of FIG. 5A aligned with the casing, according to aspects of the present disclosure.

FIG. 6A illustrates an embodiment of a thermal bus system with a single component rack, according to aspects of the present disclosure.

FIG. 6B illustrates an embodiment of the thermal bus system of FIG. 6A with stacked component racks, according to aspects of the present disclosure.

FIG. 7A illustrates an embodiment of a component module positioned within a component rack, according to aspects of the present disclosure.

FIG. 7B illustrates an embodiment of the component rack of FIG. 7A with multiple component modules, according to aspects of the present disclosure.

FIG. 8A illustrates an embodiment of a traditional component module without a covering, according to aspects of the present disclosure.

FIG. 8B illustrates an embodiment of the traditional component module of FIG. 8A with a covering, according to aspects of the present disclosure.

FIG. 9A illustrates an embodiment of a component module positioned above a cold plate, according to aspects of the present disclosure.

FIG. 9B illustrates an embodiment of the component module of FIG. 9A seated upon the cold plate, according to aspects of the present disclosure.

FIG. 10 illustrates an embodiment of a component module with an internal cooling hose arrangement, according to aspects of the present disclosure.

FIG. 11 illustrates an embodiment of a component module with a heat exchange assembly, according to aspects of the present disclosure.

### DETAILED DESCRIPTION

In the following detailed description, reference will be made to the accompanying drawing(s), in which identical functional elements are designated with like numerals. The aforementioned accompanying drawings show by way of illustration, and not by way of limitation, specific aspects, and implementations consistent with principles of this disclosure. These implementations are described in sufficient detail to enable those skilled in the art to practice the disclosure and it is to be understood that other implementations may be utilized and that structural changes and/or substitutions of various elements may be made without departing from the scope and spirit of this disclosure. The following detailed description is, therefore, not to be construed in a limited sense.

It is noted that description herein is not intended as an extensive overview, and as such, concepts may be simplified in the interests of clarity and brevity.

All documents mentioned in this application are hereby incorporated by reference in their entirety. Any process described in this application may be performed in any order and may omit any of the steps in the process. Processes may also be combined with other processes or steps of other processes.

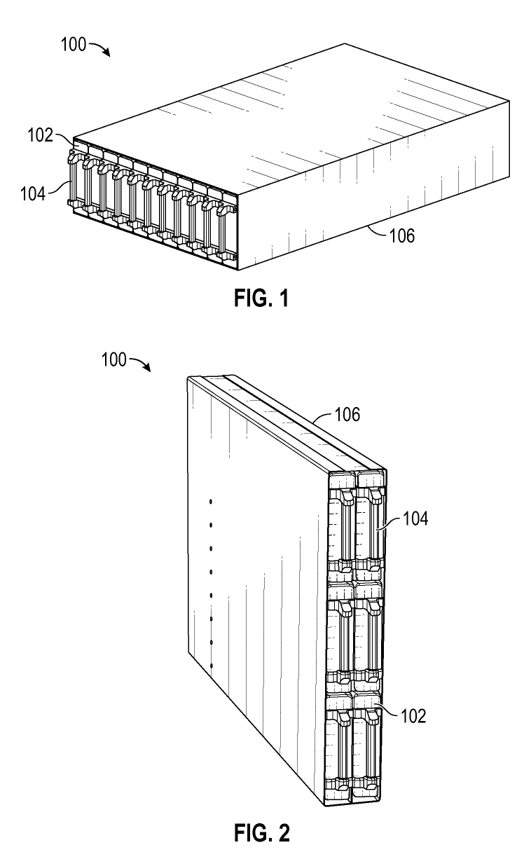

Referring to FIGS. 1 and 2, aspects of the present disclosure may relate to a modular component rack 100. The modular component rack 100 may be designed to offer flexibility in configuration, allowing arrangement in either a horizontal (as depicted in FIG. 1) or vertical (as depicted in FIG. 2) stack setups. Such adaptability is important for accommodating various spatial constraints and operational requirements in different environments.

In an embodiment, each of the horizontal and vertical setups may include a component rack 100 which may house one or more component modules 102. The component rack 100 may facilitate easy access to the component modules 102, allowing for hot-swapping capabilities as discussed in further detail below.

In one or more embodiments, each of the one or more component modules 102 may include a module removal handle (the “handle”) 104. Such a handle 104 may be positioned at, and/or interface with, a front face of each of the one or more component modules 102, to facilitate removal and insertion of the component modules 102 within the rack 100.

In an embodiment, the modular component rack 100 may include a casing 106 that houses the one or more component modules 102. For example, the casing 106 may provide structural support and define the overall form factor of the modular component rack 100. In one or more embodiments, a user may grasp the module removal handle 104 to slide the component module 102 out of, or into, the casing 106.

In some implementations, the rack 100 may be positioned on either side of a server or other computer rack to supply power to the system. Each rack 100 may be equipped with a power input, such as an AC input, which may allow for independent operation and redundancy.

Moreover, the arrangement of the one or more component modules 102 within the casing 106 may allow for scalable power distribution and redundancy configurations. In some implementations, the modular component rack 100 may include a plurality of component modules 102 arranged in an N+1 redundancy configuration, where one component module 102 serves as a backup. The N+1 redundancy configuration may allow the modular component rack 100 to maintain power output even if one component module 102 fails or requires maintenance.

The design of the modular component rack 100 may provide access to the one or more component modules 102 while maintaining a compact form factor suitable for integration into data center and/or computing environments. Each of the one or more component modules 102 may be hot-swappable, allowing for removal and replacement of individual component modules 102 without disrupting operation of other component modules 102 within the modular component rack 100. The hot-swap capability may enable maintenance and replacement operations to be performed while the modular component rack 100 continues to operate.

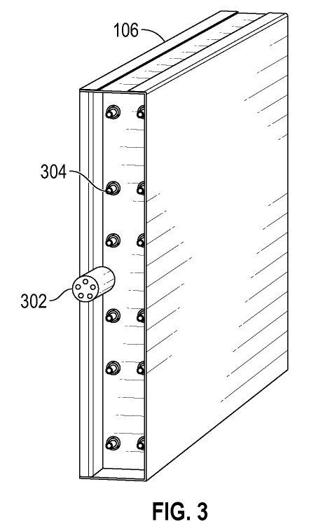

Turning to FIG. 3, a rear portion of the casing 106 is illustrated. In an embodiment, the casing 106 may include at least one of a casing power input/output 302 and a casing coolant input/output 304 positioned on the rear surface of the casing 106.

In one or more embodiments, the casing power input/output 302 may supply power to the one or more component modules 102 housed within the casing 106. The casing power input/output 302 may accommodate various electrical standards and requirements, providing compatibility with different environments and applications. In some aspects, the casing power input/output 302 may include configurations for three-phase AC input. The three-phase AC input may range from 400 to 480 volts, which may be suitable for standard industrial power applications. In some cases, other voltage inputs may be used depending on the requirements of the installation environment.

In an embodiment, the component module 102 may be a single-phase power module, which may require grouping in sets of three to support three-phase input. Alternatively, three-phase input power supplies may be used, which may remove the need to group three component modules 102. In one or more embodiments, the modular component rack 100 may include a control unit configured to control power distribution and balancing among the component modules 102.

Further, the casing coolant input/output 304 may be arranged as a series of connection points extending vertically along the rear surface of the casing 106. In an embodiment, the casing coolant input/output 304 may supply an external coolant to each of the one or more component modules 102 within the component rack 100 to maintain thermal conditions within each component module 102.

In an embodiment, the external coolant used may be water which serves as an efficient medium for transferring heat away from dielectric coolant contained within each of the component modules 102. The heat transfer between the external coolant, supplied through the casing coolant input/output 304, and the coolant within each of the one or more component modules 102 may be facilitated through a heat exchanger. In one or more embodiments, the heat exchanger may include one or more cold plates 602 and/or a heat exchange assembly 1102 (as described in more detail below). For instance, such a heat exchanger may be disposed within each of the one or more component modules 102), to ensure that the dielectric coolant within the component modules 102 remains at a stable temperature.

The arrangement of the casing coolant input/output 304 as multiple connection points may allow for individual coolant supply to each of the one or more component modules 102. The individual coolant supply may facilitate independent cooling circuits that support hot-swap functionality, enabling removal and replacement of individual component modules 102 without disrupting coolant flow to other component modules 102 within the casing 106.

The positioning of the casing power input/output 302 and the casing coolant input/output 304 at the rear of the casing 106 may enable organized cable and fluid line management. In some implementations, the casing power input/output 302 and the casing coolant input/output 304 may be located at other suitable locations on the casing 106 depending on the configuration requirements of the installation.

As previously mentioned, the component module 102 may be designed to be modular and easily hot-swappable, allowing for seamless insertion and removal from the modular component rack 100 without disrupting the operation of other component modules 102. In an embodiment, each component module 102 may include a latching mechanism that enables the module 102 to securely dock into an AC and/or DC power backplane and/or casing coolant input/outputs 304 within the component rack 100. This docking process may be streamlined through the use of blind mate power and/or fluid connections, which allow each component module 102 to connect to the necessary power and cooling systems without manual intervention, although manual connection means could be utilized.

The blind mate fluid connections may be designed to seal automatically upon disconnection, preventing coolant leakage when a component module 102 is removed from the modular component rack 100. Similarly, the blind mate power connections may disengage safely as the component module 102 is withdrawn, ensuring electrical isolation without risk of arcing or damage to the system.

In an embodiment, each component module 102 may provide DC output to a busbar system housed within or adjacent to the component rack 100 via the casing power input/output 302. In some cases, each adjacent component module 102 may supply DC output to an independent section of the DC busbar. This arrangement may allow for safe and effective current distribution throughout the component rack 100. The busbar system may be designed to handle high current loads, potentially up to 100kW per section, to accommodate the power output from multiple component modules 102.

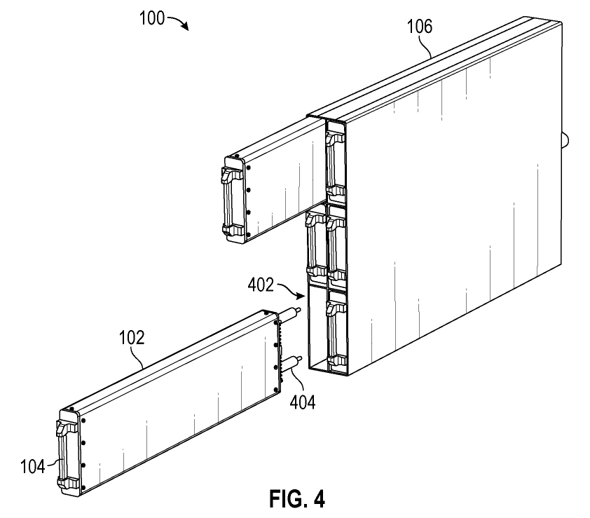

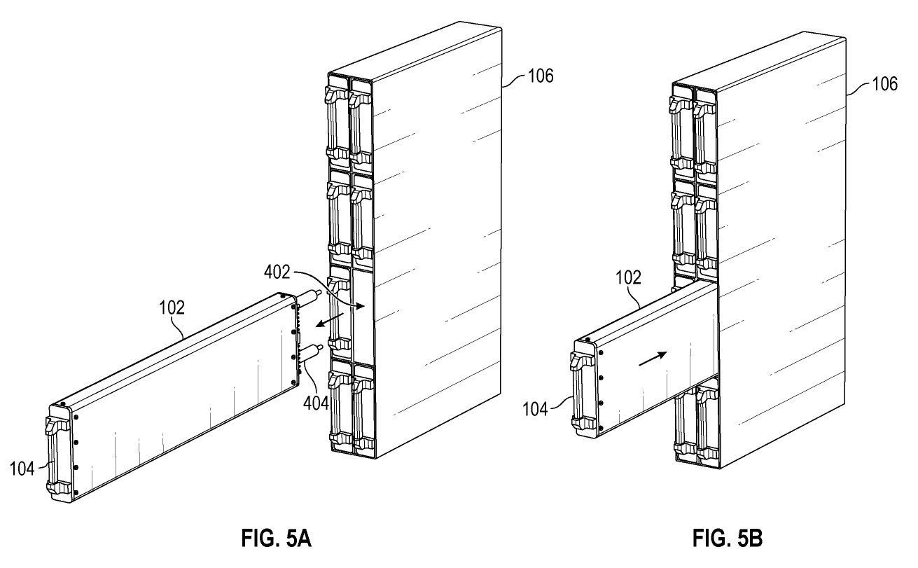

Moving to FIGS. 4-5B, the casing 106 may define a plurality of component module sockets 402. Each component module socket 402 may receive and secure an individual component module 102 within the modular component rack 100.

The component module socket 402 may include the casing power input/output 302 and/or casing coolant input/outputs 304. Said casing power input/output 302 and/or casing coolant input/outputs 304 may interface with blind mate power and fluid connections 404 disposed upon the component module 102. The blind mate power and fluid connections 404 may be configured to automatically engage when the component module 102 is inserted into the component module socket 402 and to automatically disconnect when the component module 102 is removed from the component module socket 402. The blind mate power and fluid connections 404 may allow each component module 102 to connect to power and cooling systems of the modular component rack 100 without manual intervention.

In an embodiment, the arrangement of the blind mate power and fluid connections 404 may facilitate hot-swapping of individual component modules 102 without disrupting operation of other component modules 102 within the modular component rack 100. The blind mate power and fluid connections 404 may include electrical connectors configured to provide power input to the component module 102 and fluid connectors configured to supply external coolant to the component module 102.

Furthermore, the modular component rack 100 system may enable a method for efficiently “hot-swapping” and/or removing and replacing individual component modules 102. In some aspects, hot-swapping a component module 102 may be achieved without disrupting the operation of other components in the system.

To remove a component module 102, an operator may first disengage any locking mechanisms securing the component module 102 to the component module socket 402. These mechanisms may include latches, screws, or quick-release fasteners designed for tool-less operation. Once disengaged, the operator may slide the component module 102 horizontally out of the component module socket 402. The component module 102 may be guided by rails or channels that ensure smooth extraction.

During the removal process, the blind mate power and fluid connections 404 may automatically disconnect using quick-release fittings. These fittings may be designed to seal automatically upon disconnection, preventing coolant leakage.

To replace a component module 102, the process may be reversed. The operator may align the new component module 102 with the guide rails and slide it horizontally into the component module socket 402. As the component module 102 reaches its fully inserted position, the blind mate power and fluid connections 404 may automatically engage. The locking mechanisms may then be secured to hold the module firmly in place.

In some implementations, the modular component rack 100 may include status indicators to confirm proper installation and operation of the newly inserted component module 102. These indicators may provide visual feedback to the operator, ensuring that the module is correctly seated and functioning.

The method for removing and replacing a component module 102 may be designed to minimize downtime and reduce the risk of errors during maintenance procedures. The simplicity of the process may allow for rapid servicing of the modular component rack 100 system, potentially improving overall system reliability and availability.

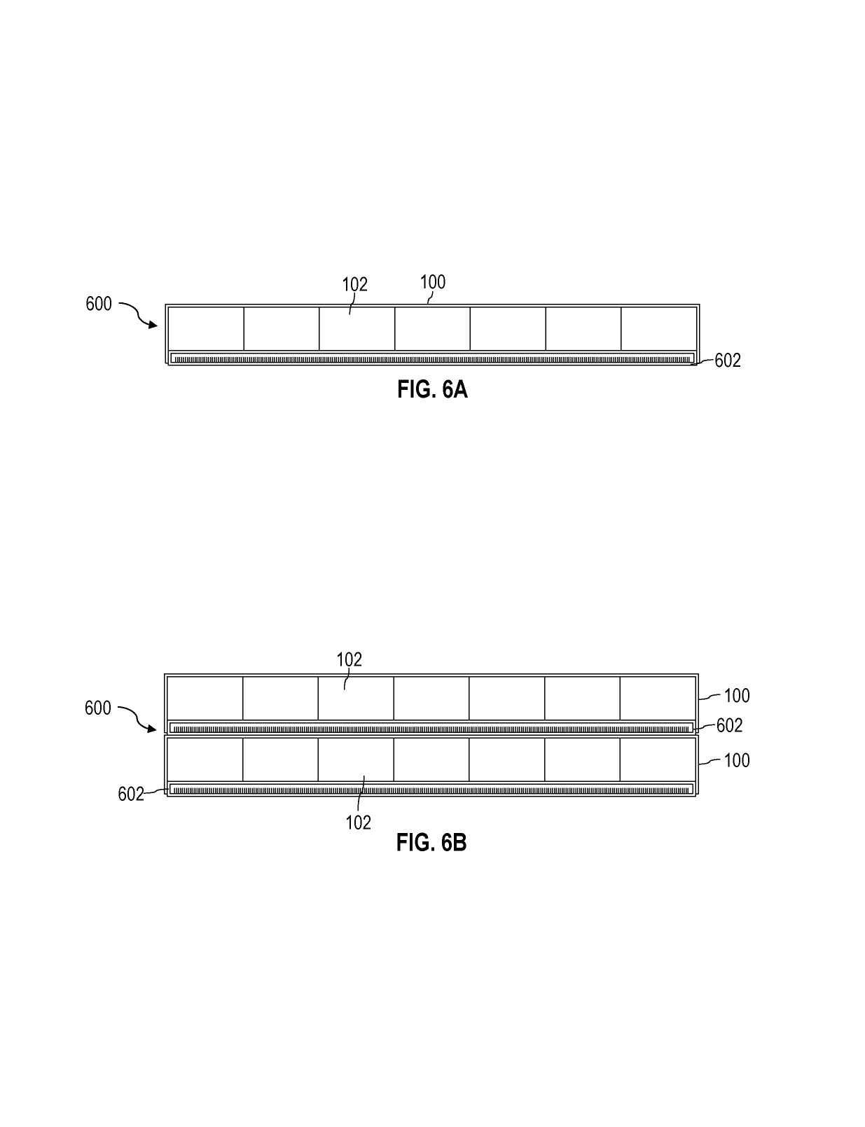

Turning to FIGS. 6A and 6B, aspects of the present disclosure may relate to a thermal bus system 600 integrated within the modular component rack 100. In an embodiment, the thermal bus system 600 may include one or more modular component racks 100. To illustrate, the thermal bus system 600 and/or the modular component rack 100 may be configured in various standard rack unit heights, such as 1U (as depicted in FIG. 6A), 2U (as depicted in FIG. 6B), or 4U high configurations, to accommodate different power capacity and/or spatial requirements. Additionally, the thermal bus system 600 may obviate the need to include coolant inputs/outputs in the individual component modules 102 (described in more detail below).

In an embodiment, the thermal bus system 600 may be comprised of one or more cold plates 602. For instance, the one or more cold plates 602 may be positioned within the modular component rack 100 such that the component module 102 sits upon said cold plates 602. Such a configuration may facilitate improved heat transfer between the component module 102 and the cold plate 602. In one embodiment, the one or more cold plates 602 may be made from a highly conductive material, such as aluminum or copper.

In some embodiments, the one or more cold plates 602 may comprise a copper pipe embedded within an aluminum block. In such embodiments, the copper pipe may follow a serpentine path through the aluminum substrate to maximize heat transfer surface area. The aluminum block may serve as a thermally conductive base that distributes heat across its surface area while the embedded copper tubing carries the external coolant.

As a nonlimiting example, the one or more cold plates 602 may serve as the base for individual component module sockets 402 within the modular component rack 100. Thus, a bottom surface of the component module 102 may interface with the cold plate 602 thereby optimizing thermal contact surface area, which necessarily improves thermal transfer between the component module 102 and the cold plate 602.

Additionally, the weight of the component module 102 may press the bottom surface of the module 102 against the top surface of the cold plate 602 to ensure sufficient thermal contact. The pressure may be further optimized by a spring system integrated within the modular component rack 100. Such a spring system may include one or more springs positioned in a roof of the component module socket 402 that push the component module 102 toward the cold plate 602. In this manner, the spring system may further promote thermal contact between the component module 102 and the one or more cold plates 602.

In one embodiment, a thermal interface material (“TIM”), such as thermal grease or paste, may be coated on the top surface of the one or more cold plates 602 to improve thermal transfer between the component module 102 and the one or more cold plates 602. Accordingly, the bottom surface of the component module 102 may not be in direct contact with the top surface of the one or more cold plates 602. Meaning, the TIM may serve as a barrier between the bottom surface of the component module 102 and the top surface of the one or more cold plates 602, to help facilitate improved thermal transfer.

As a nonlimiting example, the thermal grease may be comprised of a silicone based compound designed to conduct heat, while not conducting electricity thereby proscribing potential short circuiting of the component module 102.

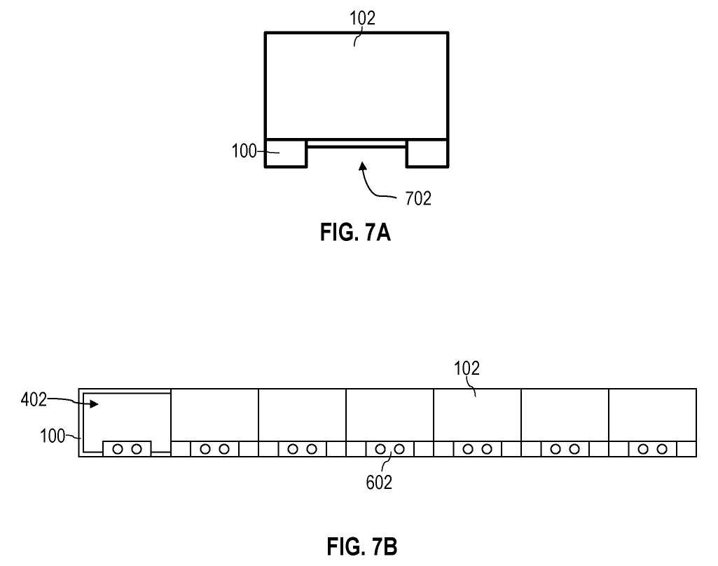

Moving to FIGS. 7A and 7B, in an embodiment, the modular component rack 100 may include a notch 702 for receiving the one or more cold plates 602. In such an embodiment, the one or more cold plates 602 may be reduced in size to accommodate the dimensions of the notch 702. That is, the surface area for thermal contact between the component module 102 and the one or more cold plates 602 may be reduced. However, the reduction in the size of the cold plates 602 may increase the pressure between the component module 102 and the cold plate 602, such that the reduction in surface area is offset.

In one or more embodiments, the one or more cold plates 602 may serve as the base for individual component module sockets 402 within the modular component rack 100. For example, the one or more cold plates 602 may be positioned within the notch 702 of the modular component rack 100.

In an embodiment, the notch 702 may prevent any TIM applied to the top surface of the one or more cold plates 602 from spreading and coming into contact with a user when hot-swapping individual component modules 102 in the modular component rack 100.

In some embodiments, the component module socket 402 may include guide rails that help the component module 102 slide in and out of the component module socket 402. Additionally, the guide rails may hold the TIM in a recess, preventing it from spreading and coming into contact with a user when hot-swapping individual component modules 102 in the modular component rack 100.

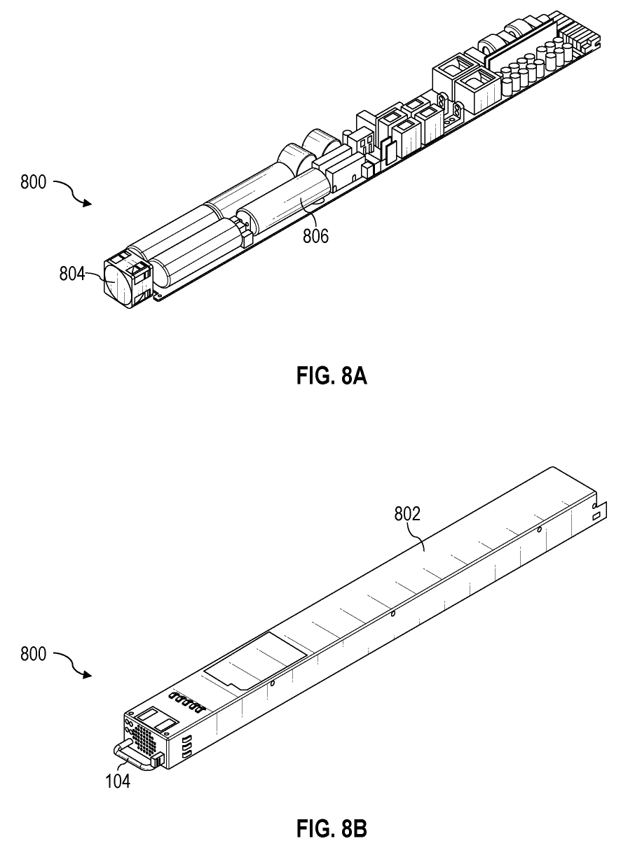

Referring to FIG. 8A and 8B, a traditional component module 800 is shown for comparison with the liquid-cooled component modules described herein. FIG. 8A illustrates a traditional component module 800 without a covering 802, and FIG. 8B illustrates the traditional component module 800 with the covering 802.

Traditional component modules 800 incorporate fan cooled systems as a means for managing heat derived from its internal components. To illustrate, said traditional modules 800 include a fan 804 to draw air through the traditional component module 800 to provide cooling for electrical components 806 disposed within the traditional component module 800. Accordingly, said modules require large amounts of power to remain operational.

The traditional component module 800 may have a standard OCP form factor allowing it to fit within a 1U rack space.

In one or more embodiments, the liquid-cooled component modules described herein may be configured to maintain a form factor compatible with the traditional component module 800. The liquid-cooled component modules may use a housing material similar to the covering 802 of the traditional component module 800, maintaining similar size and electrical properties.

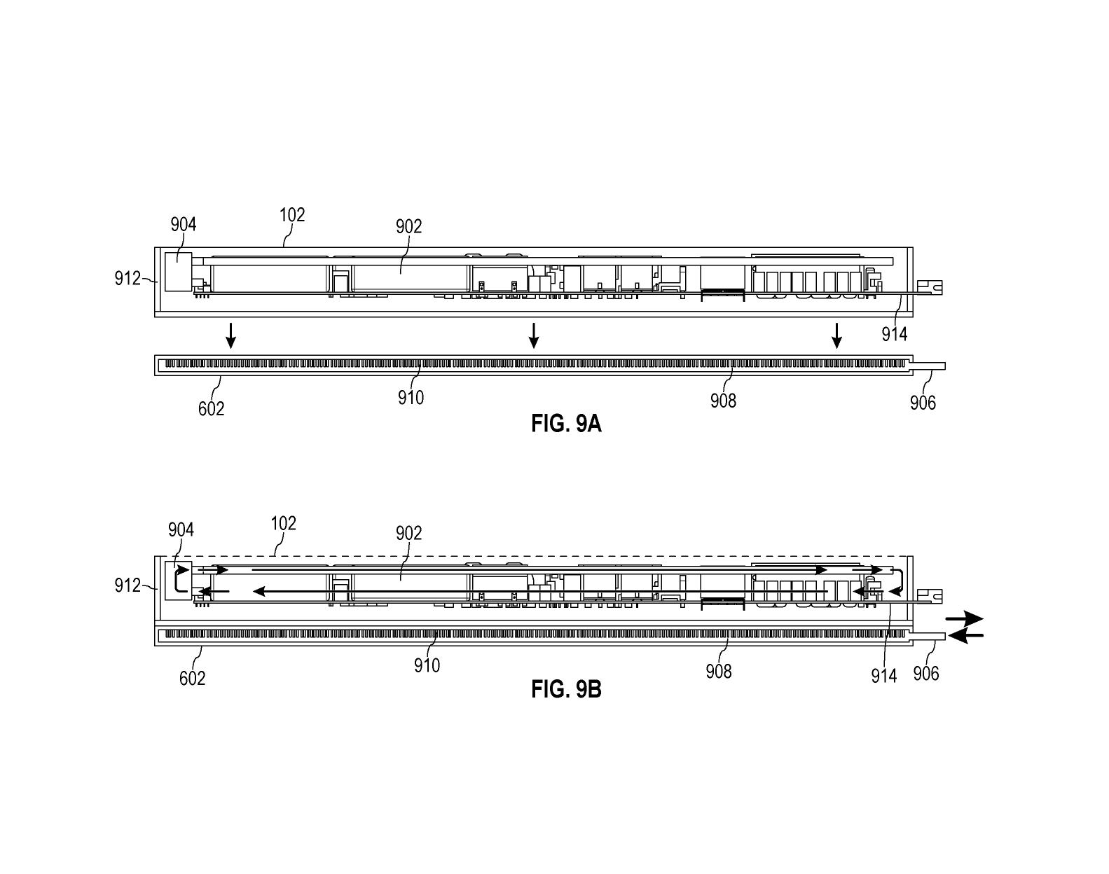

Turning to FIGS. 9A and 9B, in an embodiment, the component module 102 may house a quantity of dielectric coolant for submerging one or more internal components 902 therein. For example, the component module 102 may substitute a pump 904 for the fan 804 of the traditional component module 800. In such an example, the size of the component module 102 need not be adjusted, as the pump 904 may be sized in accordance with the fan 804, thus enabling traditional component racks to receive a component module 102 incorporating the pump 904.

In an embodiment, at least one of the modular component rack 100 and the component module 102 may feature a controller to control the rate at which dielectric coolant is pumped through the pump 904. The flow rate may be adjusted to meet varying cooling demands dependent on factors such as external ambient temperatures and the temperature of the internal components 902.

Moreover, the one or more cold plates 602 may include a coolant input/output 906 disposed at an end of said cold plates 602. Said coolant input/outputs 906 may incorporate the disclosure of the blind mate power and fluid connections 404 described above.

In an embodiment, the coolant input/outputs 906 may be designed to supply each of the one or more cold plates 602 with the external coolant to maintain and optimize thermal transfer between the component module 102 and the one or more cold plates 602. For example, the coolant used may be water, to serve as an efficient medium for transferring heat away from dielectric coolant contained within each of the component modules 102.

The one or more cold plates 602 may be further comprised of an internal cavity 908 for receiving coolant. To illustrate, external coolant (e.g., water) may enter the internal cavity 908 of the cold plate 602 via the coolant input/outputs 906. In such an illustration, said external coolant may be used to cool the cold plate 602. The external coolant may flow through the internal cavity 908 of the cold plate 602.

In an embodiment, heat generated by internal components 902 (described in more detail below) within the component module 102 may be absorbed by dielectric coolant circulating through the component module via the pump 904, subsequently transferred through the bottom surface of the module 102 to the top surface of the cold plate 602, and ultimately absorbed by external coolant in the internal cavity 908. The external coolant may then exit the cold plate 602 through the coolant input/outputs 906, carrying the absorbed heat away from the component module 102.

In an embodiment, the internal cavity 908 may house a plurality of heat fins 910 to increase the surface area within the internal cavity 908 thereby improving thermal transfer between the component module 102 and the cold plate 602. Alternatively, the internal cavity 908 may feature a plurality of pins configured to increase surface area within said cavity 908 for increasing surface area to improve thermal transfer between the component module 102 and the one or more cold plates 602. However, the heat fins 910 and/or pins may be substituted for other suitable cooling mechanisms such as, copper piping, serpentine shaped channels, etc. In yet a further embodiment, the internal cavity 908 may include a combination of the aforesaid mechanisms for increasing surface area.

In an embodiment, the dielectric coolant may be self-contained within the component module 102. That is, said coolant may not exit the component module 102. In such an embodiment, the component module 102 may feature a liquid tight end cap 912, which seals the component module 102.

For example, such a liquid tight end cap 912 may proscribe fluid communication between the interior and the exterior of the component module 102, ensuring the coolant within the component module 102 does not leak nor is exposed to an external environment thus maintaining the volume of coolant within the component module 102. For instance, the liquid tight end cap 912 may include an O-ring seal or similar sealing mechanism configured to prevent leakage of dielectric coolant from the component module 102. In an embodiment, the liquid tight end cap 912 may be disposed at the same end of the component module 102 as the pump 904.

In one or more embodiments, the dielectric coolant may be continuously pumped throughout the component module 102 via the pump 904 to ensure continuous cooling of the internal components 902. In an embodiment, the need for external coolant input/outputs may be obviated because the coolant is self-contained within the component module 102. Specifically, removing external coolant input/outputs reduces the potential for leaks. For instance, the presence of external coolant input/outputs may provide a point of failure within the component module 102, and thus removing said coolant input/outputs ameliorates the potential of said failures from occurring.

Furthermore, the dielectric coolant within the component module 102 may submerge the internal components 902, such that said coolant is thermally coupled to the internal components 902. That is, heat generated via the internal components 902 may be freely transferred to, and absorbed by, the dielectric coolant.

In an embodiment, the component module 102 may be fully flooded with dielectric coolant aside from an air gap to allow for expansion of the coolant. Such an air gap may accommodate changes in the dielectric coolant resulting from ambient temperature fluctuations. Thus, the internal components 902 may be full submerged in the dielectric coolant to improve thermal transfer from said components 902 to the coolant.

In an embodiment, the component module 102 may include a substrate 914, such as a printed circuit board (PCB). In an embodiment, the substrate 914 may be positioned within the component module 102, such that it does not obstruct the flow of dielectric coolant. Such a substrate 914 may interface with the internal components 902 within the component module 102. In particular, the substrate 914 may provide electrical connections between the internal components 902.

Moreover, the substrate 914 may be designed to withstand submersion in the dielectric coolant contained within the component module 102. For example, such a substrate 914 may include protective coatings to prevent damage while submerged in coolant.

Yet further, the substrate 914 may extend outside of the component module 102 to interface with the power input/output 302 described above. In an embodiment, the portion of the substrate 914 extending out from the component module 102 may be an extension of a base board PCB within the component module 102. In such an embodiment, the extension of the substrate 914 may pass through a back wall of the component module 102 to provide power and communication connections, and may be sealed to prevent potential leakage of the dielectric coolant residing within said module 102.

As mentioned above, the internal components 902 residing within the component module 102 may be submerged in coolant. Thus, heat generated by said components 902 may be transferred to, and absorbed, by the coolant.

In one or more embodiments, the internal components 902 may include heat generating electronic components, including, but not limited to, power supply units, power conversion components, transformers, capacitors, computing components such as CPUs, GPUs, DIMMs, or other processing and memory devices.

Upon absorbing heat from the internal components 902, the warmed dielectric coolant may be cooled via the cold plate 602 upon which the component module 102 sits. To illustrate, the warmed dielectric coolant may interface with a bottom of the component module 102, such that heat within said coolant is transferred to, and absorbed by, the bottom of the component module 102, which is subsequently transferred to the one or more cold plates 602 and removed from the system by the external coolant, thus cooling the dielectric coolant within the component module 102. The cooled dielectric coolant is then pumped, via the pump 904, from a first end of the component module 102, to the second end of the component module 102, to continuously cool the internal components 902.

Further, the bottom surface of the component module 102, upon absorbing heat from the warmed dielectric coolant, may transfer said heat to the one or more cold plates 602 via the TIM. Ultimately, heat transferred to the cold plate 602 may be dissipated and removed from the system via the external coolant entering the internal cavity 908 of the cold plate 602, via the coolant input/outputs 906.

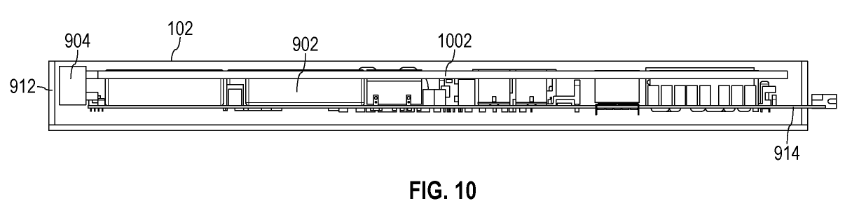

Referring to FIG. 10, the component module 102 as described herein may also incorporate a cooling hose 1002 affixed to the pump 904. In an embodiment, said hose 1002 may transfer dielectric coolant from a first end of the component module 102 to a second end of said module 102. In such an embodiment, the hose 1002 may run the length of the component module 102.

In an embodiment, the hose 1002 may be routed between internal components 902 to avoid adding any height to the component module 102. In some cases, the hose 1002 may follow a route similar to that of a pump power cable in traditional air-cooled modules.

Yet further, the cooling hose 1002 may be formed from a resilient material. To illustrate, such a hose 1002 may fit between internal components 902 residing within the component module 102. That is, the hose’s 1002 ability to be arranged between the internal components 902 ensures that the component module 102 maintains an identical size to that of traditional component modules 800, such that the component module 102 described herein may easily replace said traditional component modules 800.

Furthermore, upon absorbing heat from the internal components 902, the warmed dielectric coolant may be cooled via the cold plate 602 upon which the component module 102 sits. To illustrate, the warmed dielectric coolant may interface with a bottom of the component module 102, such that heat within said coolant is transferred to, and absorbed by, the bottom of the component module 102, which is subsequently transferred to the one or more cold plates 602 and removed from the system by the external coolant, thus cooling the dielectric coolant within the component module 102. The cooled dielectric coolant is then pumped, via the pump 904, from a first end of the component module 102, through the hose 1002, to the second end of the component module 102, to continuously cool the internal components 902.

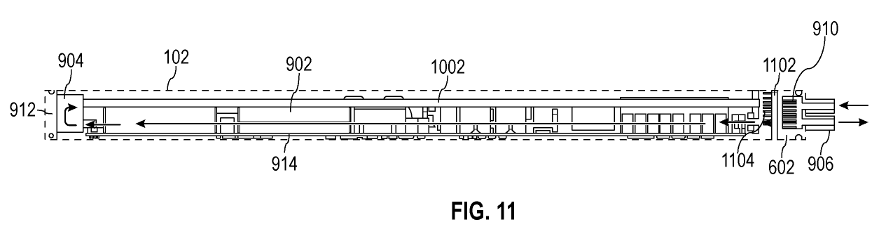

Referring to FIG. 11, in an embodiment, the one or more cold plates 602 may be disposed at an end of the component module 102. In particular, the one or more cold plates 602 may be disposed at an end of the module 102 opposite that of the pump 904.

In such an embodiment, the component module 102 may feature a heat exchange assembly 1102 in thermal contact with the one or more cold plates 602. In one or more embodiments, the heat exchange assembly 1102 may be made from copper or another thermally conductive material. The heat exchange assembly 1102 may include skived heat fins or equivalent structures that transfer heat from the dielectric coolant to the facility coolant (i.e., the external coolant in the cold plates).

As depicted in FIG. 11, the thermal interface between the heat exchange assembly 1102 and the one or more cold plates 602 may be flat. In some embodiments, the thermal interface between the heat exchange assembly 1102 and the cold plate 602 may be ridged or tessellated to increase surface area. Moreover, such a thermal interface may include tapered ridges to improve thermal contact between the heat exchange assembly 1102 and the one or more cold plates 602.

The heat exchange assembly 1102 may include a plurality of heat fins 1104, or any suitable alternative thereof (e.g., pins), for increasing surface area within the component module 102 thereby improving thermal transfer between the dielectric coolant and the heat exchange assembly 1102. Said fins 1104, or suitable alternative thereof, may ensure heat is evenly distributed from the dielectric coolant to the heat exchange assembly 1102.

The heat exchange assembly 1102 may interface with the one or more cold plates 602 within the modular component rack 100. Thus, heat received by the heat exchange assembly 1102 from the dielectric coolant may ultimately be transferred to said cold plates 602 thereby improving thermal management of the component module 102. Additionally, the internal cavity 908 of the one or more cold plates 602 may also feature the plurality of heat fins 910, or suitable alternative thereof, for increasing surface area within the internal cavity 908 to improve thermal transfer from the heat exchange assembly 1102 to the one or more cold plates 602.

Moreover, a layer of TIM (e.g., thermal grease) may serve as a barrier between the component module 102 and the one or more cold plates 602. Specifically, the TIM may be applied to at least one of an external surface of the heat exchange assembly 1102 and a side surface of the one or more cold plates 602.

In an embodiment, the dielectric coolant may receive heat from the internal components 902 as described above. Subsequently, the warm coolant may be pumped, via the pump 904, through the hose 1002, to transfer heat from the warmed dielectric coolant to the heat exchange assembly 1102.

For instance, the heat exchange assembly 1102 may absorb heat from the warmed dielectric coolant, prior to it being recirculated to the internal components 902. After being cooled by the heat exchange assembly 1102, the cooled dielectric coolant is recirculated throughout the component module 102 to continuously cool the internal components 902 therein. Ultimately, the heat absorbed by the heat exchange assembly 1102 may be removed via the one or more cold plates 602 in contact with the component module 102.

In one or more embodiments, the component rack may include one or more component modules, each configured to contain a different coolant. For example, a first component module may contain a first coolant, while a second component module may contain a second coolant. The use of such different coolants within the respective component modules may facilitate targeted cooling of different electrical components housed therein.

In accordance with aspects of the present disclosure, a system for cooling electronic components may be provided. The system may comprise a component rack 100 and one or more component modules 102 disposed within the component rack 100. Each of the one or more component modules 102 may include one or more internal components 902 and a dielectric coolant contained within an internal volume of each of the one or more component modules 102. The dielectric coolant may at least partially submerge the one or more internal components 902. Each of the one or more component modules 102 may include a pump 904 configured to circulate the dielectric coolant within the component module 102. The system may comprise one or more cold plates 602 including an internal cavity 908 configured to receive an external coolant. Heat absorbed by the dielectric coolant from the one or more internal components 902 may be transferred to the external coolant via the one or more cold plates 602.

In some aspects, the internal cavity 908 may include a plurality of heat fins 910 to increase surface area within the internal cavity 908. The one or more cold plates 602 may further comprise a coolant input and a coolant output, each of the coolant input and the coolant output disposed at an end of the one or more cold plates 602. The internal cavity 908 may receive cool external coolant via the coolant input, and the internal cavity 908 may reject warmed external coolant via the coolant output.

In some aspects, the component rack 100 may further comprise one or more component module sockets 402 that receive and house the one or more component modules 102. The one or more cold plates 602 may serve as a base for the one or more component module sockets 402 within the component rack 100. Each of the one or more component module sockets 402 may include a notch 702 configured to receive the one or more cold plates 602.

In some aspects, the one or more component modules 102 may further comprise a cooling hose 1002 that transfers the dielectric coolant from a first end of the component module 102 to a second end of the component module 102 via the pump 904. A bottom surface of each of the one or more component modules 102 may be in thermal contact with a top surface of at least one of the one or more cold plates 602. A thermal interface material may be disposed between the bottom surface of each of the one or more component modules 102 and the top surface of the one or more cold plates 602.

In some aspects, the component rack 100 may include a spring system configured to press each of the one or more component modules 102 toward the one or more cold plates 602. The spring system may include one or more springs positioned in a roof of each of the one or more component module sockets 402.

In some aspects, the one or more component modules 102 may further comprise a heat exchange assembly 1102 in thermal contact with the one or more cold plates 602. The heat exchange assembly 1102 may include a plurality of heat fins 1104 configured to increase surface area within the component module 102.

In accordance with another aspect of the present disclosure, a system for cooling electronic components may be provided. The system may comprise a component rack 100 including one or more component module sockets 402 and one or more component modules 102 disposed within each of the one or more component module sockets 402. Each of the one or more component modules 102 may include one or more internal components 902 and a dielectric coolant contained within an internal volume of each of the one or more component modules 102. The dielectric coolant may partially submerge the one or more internal components 902. Each of the one or more component modules 102 may include a pump 904 configured to circulate the dielectric coolant within the component module 102. The system may comprise one or more cold plates 602 including an internal cavity 908 configured to receive an external coolant. Heat absorbed by the dielectric coolant from the one or more internal components 902 may be transferred to the external coolant via the one or more cold plates 602.

In some aspects, the internal cavity 908 may include a plurality of heat fins 910 to increase surface area within the internal cavity 908. The one or more cold plates 602 may further comprise a coolant input and a coolant output, each of the coolant input and the coolant output disposed at an end of the one or more cold plates 602. The internal cavity 908 may receive cool external coolant via the coolant input, and the internal cavity 908 may reject warmed external coolant via the coolant output.

In some aspects, the one or more component modules 102 may further comprise a heat exchange assembly 1102 in thermal contact with the one or more cold plates 602. The heat exchange assembly 1102 may include a plurality of heat fins 1104 configured to increase surface area within the component module 102. The one or more cold plates 602 may serve as a base for the one or more component module sockets 402 within the component rack 100. Each of the one or more component module sockets 402 may include a notch 702 configured to receive the one or more cold plates 602.

Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

Various elements, which are described herein in the context of one or more embodiments, may be provided separately or in any suitable subcombination. Further, the processes described herein are not limited to the specific embodiments described. For example, the processes described herein are not limited to the specific processing order described herein and, rather, process blocks may be re-ordered, combined, removed, or performed in parallel or in serial, as necessary, to achieve the results set forth herein.

It will be further understood that various changes in the details, materials, and arrangements of the parts that have been described and illustrated herein may be made by those skilled in the art without departing from the scope of the following claims.

All references, patents and patent applications and publications that are cited or referred to in this application are incorporated in their entirety herein by reference. Finally, other implementations of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

What is claimed is:

1. A system for cooling electronic components, comprising:
a component rack;
one or more component modules disposed within the component rack, each of the one or more component modules including:
one or more internal components;
a dielectric coolant contained within an internal volume of each of the one or more component modules,
wherein the dielectric coolant at least partially submerges the one or more internal components; and
a pump configured to circulate the dielectric coolant within the component module; and
one or more cold plates including an internal cavity configured to receive an external coolant,
wherein heat absorbed by the dielectric coolant from the one or more internal components is transferred to the external coolant via the one or more cold plates.

2. The system of claim 1, wherein the internal cavity includes a plurality of heat fins to increase surface area within the internal cavity.

3. The system of claim 1, wherein the one or more cold plates further comprise:
a coolant input; and
a coolant output;
each of the coolant input and the coolant output disposed at an end of the one or more cold plates,
wherein the internal cavity receives cool external coolant via the coolant input, and
wherein the internal cavity rejects warmed external coolant via the coolant output.

4. The system of claim 1, wherein the component rack further comprises:
one or more component module sockets that receive and house the one or more component modules.

5. The system of claim 4, wherein the one or more cold plates serve as a base for the one or more component module sockets within the component rack.

6. The system of claim 4, wherein each of the one or more component module sockets includes a notch configured to receive the one or more cold plates.

7. The system of claim 1, wherein the one or more component modules further comprise:
a cooling hose that transfers the dielectric coolant from a first end of the component module to a second end of the component module via the pump.

8. The system of claim 1, wherein a bottom surface of each of the one or more component modules is in thermal contact with a top surface of at least one of the one or more cold plates.

9. The system of claim 8, wherein a thermal interface material is disposed between the bottom surface of each of the one or more component modules and the top surface of the one or more cold plates.

10. The system of claim 4, wherein the component rack includes a spring system configured to press each of the one or more component modules toward the one or more cold plates.

11. The system of claim 10, wherein the spring system includes one or more springs positioned in a roof of each of the one or more component module sockets.

12. The system of claim 1, wherein the one or more component modules further comprise:
a heat exchange assembly in thermal contact with the one or more cold plates.

13. The system of claim 12, wherein the heat exchange assembly includes a plurality of heat fins configured to increase surface area within the component module.

14. A system for cooling electronic components, comprising:
a component rack including one or more component module sockets;
one or more component modules disposed within each of the one or more component module sockets, each of the one or more component modules including:
one or more internal components;
a dielectric coolant contained within an internal volume of each of the one or more component modules,
wherein the dielectric coolant partially submerges the one or more internal components; and
a pump configured to circulate the dielectric coolant within the component module; and
one or more cold plates including an internal cavity configured to receive an external coolant,
wherein heat absorbed by the dielectric coolant from the one or more internal components is transferred to the external coolant via the one or more cold plates.

15. The system of claim 14, wherein the internal cavity includes a plurality of heat fins to increase surface area within the internal cavity.

16. The system of claim 14, wherein the one or more cold plates further comprise:
a coolant input; and
a coolant output;
each of the coolant input and the coolant output disposed at an end of the one or more cold plates,
wherein the internal cavity receives cool external coolant via the coolant input, and
wherein the internal cavity rejects warmed external coolant via the coolant output.

17. The system of claim 14, wherein the one or more component modules further comprise:
a heat exchange assembly in thermal contact with the one or more cold plates.

18. The system of claim 17, wherein the heat exchange assembly includes a plurality of heat fins configured to increase surface area within the component module.

19. The system of claim 14, wherein the one or more cold plates serve as a base for the one or more component module sockets within the component rack.

20. The system of claim 19, wherein each of the one or more component module sockets includes a notch configured to receive the one or more cold plates.
